(19) United States
(12) Patent Application Publication
(10) Pub. No.: US 2008/0096364 A1
(43) Pub. Date: Apr. 24, 2008

(54) Conformal liner for gap-filling

(75) Inventors: Erik Wilson, Santa Clara, CA (US); Minh-Van Ngo, Fremont, CA (US); Hieu Pham, Milpitas, CA (US); Robert Huertas, Hollister, CA (US); Lu You, San Jose, CA (US); Hirokazu Tokuno, Cupertino, CA (US); Alexander Nickel, Santa Clara, CA (US); Minh Tran, Milpitas, CA (US)

Correspondence Address: MCDERMOTT WILL & EMERY LLP, 600 13TH STREET, N.W., WASHINGTON, DC, 20005-3096, US

(73) Assignees: SPANSION LLC; ADVANCED MICRO DEVICES, INC.

(21) Appl. No.: 11/582,442

(22) Filed: Oct. 18, 2006

(51) Int. Cl. H01L 21/76

(52) U.S. Cl. 438/424

(57) ABSTRACT

Gap filling between features which are closely spaced is significantly improved by initially depositing a thin conformal layer followed by depositing a layer of gap filling dielectric material. Embodiments include depositing a thin conformal layer of silicon nitride or silicon oxide, as by atomic layer deposition or pulsed layer deposition, into the gap between adjacent gate electrode structures such that it flows into undercut regions of dielectric spacers on side surfaces of the gate electrode structures, and then depositing a layer of BPSG or P-HDP oxide on the thin conformal layer into the gap. Embodiments further include depositing the layers at a temperature less than 430° C., as by depositing a P-HDP oxide after depositing the conformal liner when the gate electrode structures include a layer of nickel silicide.

### FIELD OF THE INVENTION

The present invention relates to a method of manufacturing semiconductor devices exhibiting high reliability, and to the resulting semiconductor devices. The present invention enjoys particular applicability in fabricating flash memory devices with improved data retention and improved gap filling.

### BACKGROUND OF THE INVENTION

Semiconductor memory devices, such as erasable, programmable, read-only memories (EPROMs), electrically erasable programmable read-only memories (EEPROMs), and flash erasable programmable read-only memories (FEPROMs) are erasable and reusable, and are employed in various commercial electronic devices, such as computers, cellular telephones and digital cameras. There has recently evolved devices termed mirrorbit devices which do not contain a floating gate electrode. In mirrorbit devices, the gate electrode is spaced apart from the substrate by an oxide/nitride/oxide (ONO) stack, such as a silicon oxide/silicon nitride/silicon oxide stack. In such devices the charge is contained within the nitride layer of the ONO stack. The relentless drive for miniaturization has led to the fabrication of various types of flash memory devices comprising transistors having a gate width of about 150 nm and under, and gate structures spaced apart by a gap of 225 nm or less. Conventional practices comprise forming a sidewall spacer on side surfaces of the gate stack, thereby reducing the gate gap to about 25 nm.

As device dimensions shrink into the deep sub-micron regime, and the spacing between gate electrode structures decreases with increasing aspect ratio, such as at an aspect ratio of 3:1 or greater, it becomes increasingly more difficult to completely fill the gaps. Exacerbating this problem, conventional fabrication techniques result in the formation of undercut regions on sidewall spacers of gate electrodes, typically proximate the upper layer of metal silicide and proximate the substrate. It is believed that such undercutting stems in part from undercutting the oxide liner during wet etching with dilute hydrofluoric acid prior to metal deposition in implementing salicide technology. Further, subsequent to silicidation, etching is conducted to remove unreacted metal remaining on the sidewall spacers, thereby attacking silicon under the spacers and exasperating the undercut regions. The inability to adequately fill gaps between neighboring transistors, particularly the undercut regions in dielectric sidewall spacers, leads to void formation and open contacts with consequential shorting causing leakage and low production yields.

A pre-metal dielectric layer or the first interlayer dielectric (ILD0) is typically deposited over the gate structures filling the gaps, followed by rapid thermal annealing. Conventional practices comprise depositing a boron, phosphorous-doped silicon oxide derived from tetraethyl orthosilicate (BPTEOS) or a phosphorous-doped high density plasma (P-HDP) oxide as the ILD0. Such conventional gap-filling practices fall short of adequately addressing the void formation problem, particularly the problem of adequately filling undercut regions in dielectric sidewall spacers. For example, P-HDP oxide does not exhibit sufficient fluidity to completely fill closely spaced apart high aspect ratio gaps, let alone the undercut regions in dielectric sidewall spacers. BPTEOS requires high temperature annealing, as at a temperature of about 720° C. to about 840° C. Such high temperature annealing is antithetic to the desired use of nickel silicide for salicide technology. Nickel silicide is desirable because it can be formed in a single heating step at a relatively low temperature, with an attendant reduction in consumption of silicon in the substrate, thereby enabling the formation of ultra-shallow source/drain junctions.

Accordingly, there exists a need for semiconductor memory devices with improved reliability, increased operating speed and reduced device leakage. There exists a particular need for methodology enabling the fabrication of flash memory devices, such as flash mirrorbit devices, comprising nickel silicide, with improved reliability and high manufacturing throughout.

### DISCLOSURE OF THE INVENTION

An advantage of the present invention is a method of manufacturing semiconductor devices with improved reliability and high manufacturing throughput.

Another advantage of the present invention is a semiconductor device exhibiting improved reliability.

Additional advantages and other features of the present invention will be set forth in the description which follows and in part will be apparent to those having ordinary skill in the art upon examination of the following or may be learned from the practice of the present invention. The advantages of the present invention may be realized and obtained as particularly pointed out in the appended claims.

According to the present invention, the foregoing and other advantages are achieved in part by a method of manufacturing a semiconductor device, the method comprising: forming two gate electrode structures, spaced apart by a gap, on a semiconductor substrate; forming dielectric sidewall spacers, having undercut regions, on side surfaces of the gate electrode structures; depositing a conformal dielectric liner of (a) silicon oxide at a thickness of about 50 Å to about 500 Å; or (b) a material other than silicon oxide into the gap and into the undercut regions; and depositing a layer of dielectric material on the conformal dielectric liner and into the gap.

Certain embodiments of the present invention include depositing the conformal dielectric liner, the dielectric liner comprising a dielectric including, but not limited to (a) silicon oxide at a thickness of about 50 Å to about 500 Å; (b) silicon nitride; (c) silicon oxynitride; (d) silicon carbide; or (e) silicon oxycarbide. In yet other embodiments, the silicon oxide includes nitrogen and carbon content.

Embodiments of the present invention include forming sidewall spacers comprising an oxide liner, such as silicon oxide, extending along a side surface of the gate electrode stack and along an upper surface of the substrate, and a nitride layer, such as silicon nitride, on the oxide liner. Embodiments of the present invention further include depositing the dielectric liner by atomic layer deposition or pulsed layer deposition, at a thickness of about 50 Å to about 500 Å, such as at a thickness of about 10 to 100 atomic layers, e.g. about 50 atomic layers. After deposition of the conformal dielectric liner, the gap between the gate electrode stacks can be filled by one or more dielectric layers, as by depositing a layer of BPSG and annealing at a temperature of about 720° C. to about 840° C., or by depositing a layer of P-HDP oxide without annealing, particularly when the gate electrode structures comprise an upper layer of nickel silicide.

Another advantage of the present invention is a semiconductor device comprising: two gate electrode structures, spaced apart by a gap, on a semiconductor substrate; dielectric sidewall spacers, having undercut portions, on side surfaces of the gate electrode structures; a conformal dielectric liner comprising: (a) silicon oxide at a thickness of about 50 Å to about 500 Å; or (b) a material other than silicon oxide into the gap and into the undercut regions; and a layer of dielectric material on the conformal dielectric liner in the gap.

Certain embodiments of the present invention include flash memory devices wherein the conformal dielectric liner comprises a dielectric including, but not limited to (a) silicon oxide at a thickness of about 50 Å to about 500 Å; (b) silicon nitride; (c) silicon oxynitride; (d) silicon carbide; or (e) silicon oxycarbide. In yet other embodiments, the silicon oxide includes nitrogen and carbon content.

Embodiments of the present invention include various types of memory devices, including flash mirrorbit devices. Accordingly, embodiments of the present inventions relate to filling gaps between closely spaced apart gate electrode structures having a gate dielectric layer comprising a first oxide layer, such as a silicon oxide layer, on the substrate, a nitride layer, such as silicon nitride, on the first oxide layer, and a second oxide layer, such as a silicon oxide layer, on the nitride layer, and a gate electrode on the gate dielectric stack.

Additional advantages of the present invention will become readily apparent to those skilled in this art from the following detailed description wherein embodiments of the present invention are described simply by way of illustration of the best mode contemplated to carry out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### BRIEF DESCRIPTION OF THE DRAWINGS

FIGS. 1 through 3 schematically illustrate an embodiment of the present invention.

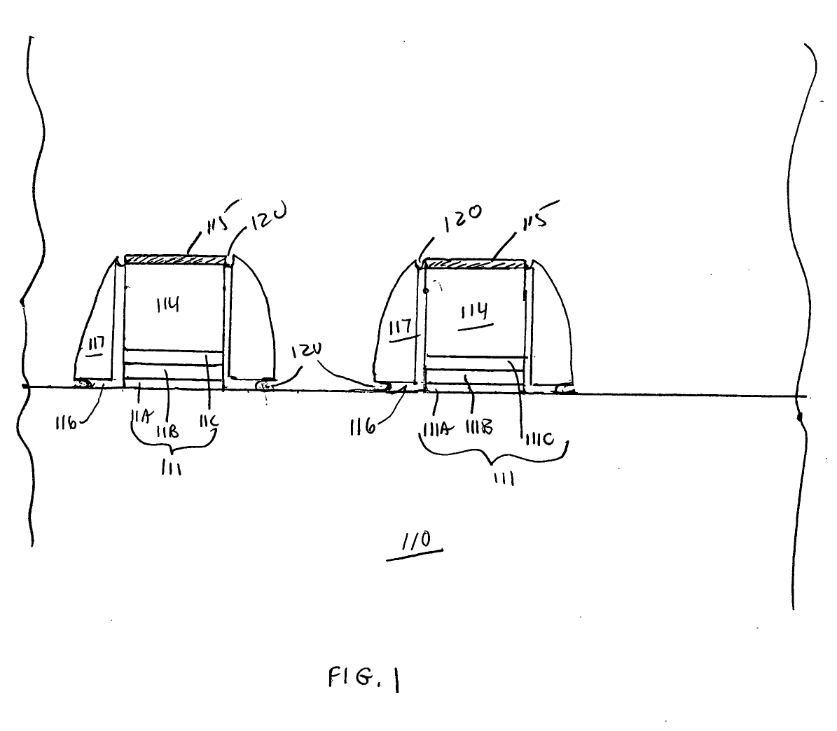

In FIGS. 1 through 3, similar features or elements are denoted by similar reference characters.

### DESCRIPTION OF THE INVENTION

The present invention addresses and solves various reliability problems attendant upon conventional semiconductor fabrication techniques. These problems arise as semiconductor memory device dimensions continue to shrink, making it increasingly more difficult to deposit an ILD0 to effectively fill high aspect ratio gaps between closely spaced apart gate electrode structures, particularly wherein the gate electrode stacks comprise spacers with undercut regions. The inability to effectively fill such high aspect ratio gaps leads to various reliability problems and reduced yields.

The present invention addresses and solves that problem, and provides methodology enabling the fabrication of gate electrode structures with nickel silicide layers, by strategically depositing an extremely thin conformal layer of silicon oxide or silicon nitride as a liner in the gap and into the undercut portions. The silicon oxide liner can be deposited by various techniques, such as atomic layer deposition, pulsed deposition or subatmospheric chemical vapor deposition (SACVD) employing tetraethyl orthosilicate (TEOS) and ozone (O₃). The conformal silicon nitride layer can be deposited by atomic layer deposition, pulsed deposition or plasma enhanced chemical vapor deposition (PECVD).

Embodiments of the present invention include depositing the conformal silicon nitride or silicon oxide liner at a thickness of about 50 Å to about 500 Å, as at a thickness of 10 to 100 atomic layers, e.g. 50 atomic layers, with thickness sufficient to seal off the undercut region by the conformally deposited first layer deposition.

Gap filling is then implemented by depositing one or more layers of dielectric material. For example, gap filling can be effected by depositing a layer of BPSG followed by rapid thermal annealing at a temperature of about 720° C. to about 840° C. However, when the transistors contain nickel silicide layers, the deposition of the dielectric liner and gap filling are implemented at a temperature less than about 430° C. Accordingly, in applying the inventive methodology to gap filling between transistors having an upper nickel silicide layer, it is desirable to deposit P-HDP oxide without any annealing. Gap filling with P-HDP oxide can be implemented at a temperature below 430° C., while deposition of the conformal liner can be implemented at a temperature of about 150° C. to about 350° C. Agglomeration of nickel silicide is prevented by maintaining the temperature of ILD0 below 430° C. during formation.

The inventive sequence of initially depositing a conformal liner, as by atomic layer deposition, advantageously enables deposition of the gap fill dielectric, such as an HDP oxide, at a higher etch/deposition rate, because the conformal liner provides protection against plasma damage and/or clipping the structure. In accordance with embodiments of the present invention, gap filling after conformal liner deposition can be conducted at a high bias power to achieve a sputter to deposition ratio of up to or about 0.4 where the sputter to deposition ratio is calculated by measuring the deposition rate of a process and then measuring the sputter rate of the process after removing the silicon precursor as given by the following equation: sputter to deposition ratio=sputter rate/(sputter rate+deposition rate).

Mirrorbit technology is fundamentally different and more advanced than conventional floating gate technology, thereby enabling innovative and cost-effective advancements. A mirrorbit cell doubles the intrinsic density of a flash memory array by storing two physically distinct bits on opposite sides of a memory cell, typically within the nitride layer of the ONO stack of the gate dielectric layer separating the gate from the substrate. Each bit within a cell serves as a binary unit of data, e.g., either 1 or 0, mapped directly to the memory array. Reading or programming one side of a memory cell occurs independently of whatever data is stored on the opposite side of the cell. Consequently, mirrorbit technology delivers exceptional read and write performance for wireless and embedded markets.

An embodiment of the present invention comprising a flash memory mirrorbit device is schematically illustrated in FIGS. 1 through 3, wherein similar features are denoted by similar reference characters. Adverting to FIG. 1, spaced apart gate electrode structures of a mirrorbit device are formed on substrate 110. For illustrative convenience, the associated source/drain regions are not illustrated. Each gate electrode stack comprises a gate dielectric layer 111 formed of a composite ONO stack comprising silicon oxide layer 111A, silicon nitride layer 111B, and silicon oxide layer 111C, and a gate electrode 114 formed thereon. Typically, sidewall spacers are formed on side surfaces of the gate electrode stack, which sidewall spacers can include a silicon oxide liner 116 and silicon nitride spacers 117. A metal silicide layer 115, such as cobalt silicide or nickel silicide, can be formed on the gate electrode 114.

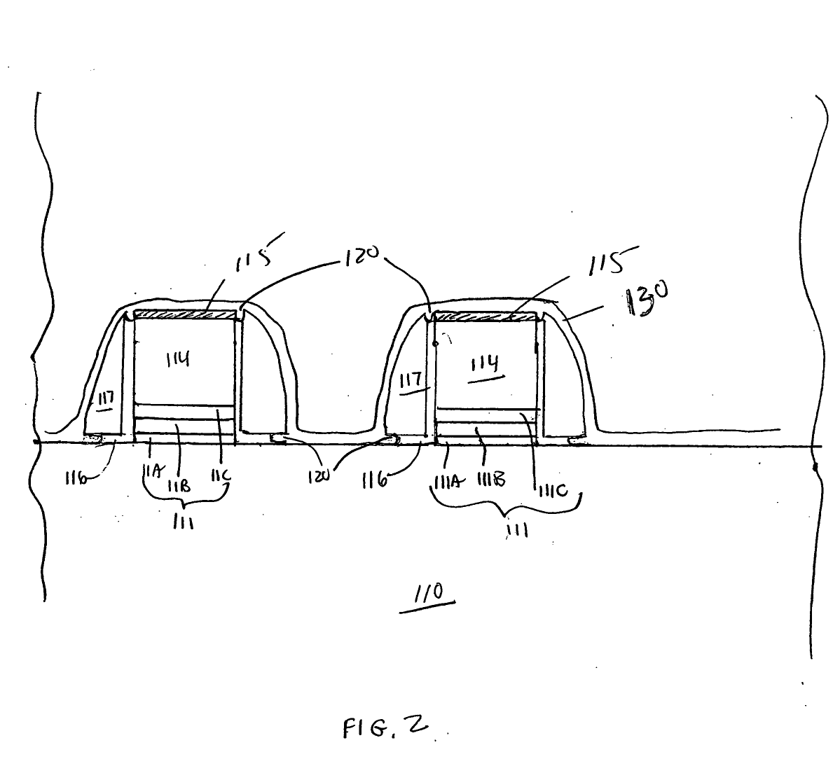

With continued reference to FIG. 1, undercut regions 120 are formed in the sidewall spacers proximate the metal silicide layer 15 and proximate the substrate 110. Such undercut regions are believed to be formed during wet cleaning with dilute hydrochloric acid prior to metal deposition in implementing salicide technology. In accordance with the present invention, the problem of adequately filling the gap between the gate electrode structures and adequately filling undercut regions 120 is addressed by depositing a thin conformal layer 130 of silicon oxide or silicon nitride, as by atomic layer deposition or pulsed deposition, typically at a thickness of about 50 Å to about 500 Å, such as 10 to 100 atomic layers, e.g. 50 atomic layers, as shown in FIG. 2. The thin conformal oxide or nitride layer 130 seals the undercut regions 120, thereby preventing void formation and undesirable leakage problems.

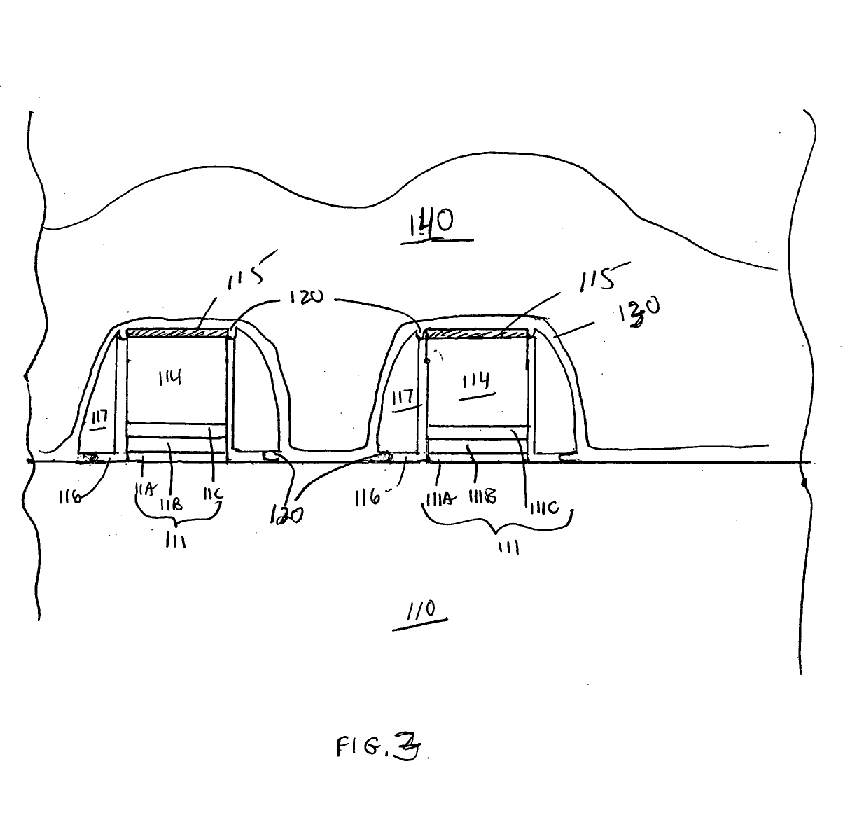

Subsequently, as illustrated in FIG. 3, gap filling is implemented by depositing dielectric layer 140. Dielectric layer 140 can be deposited in one or more layers. Typically, gap filling is implemented by depositing a layer of BPSG and annealing at a temperature of about 720° C. to about 840° C. However, in forming gate electrode structures comprising a layer of nickel silicide as the metal silicide 115, it is desirable to employ temperatures below 430° C. to prevent agglomeration of the nickel silicide. Accordingly, when employing nickel silicide, the conformal dielectric liner 130 can be deposited at temperatures of about 150° C. to about 350° C., and the dielectric layer 140 can comprise P-HDP oxide deposited at a temperature of less than 430° C., without post deposition annealing.

The present invention provides methodology enabling the fabrication of various types of semiconductor devices, e.g., semiconductor memory devices, particularly high speed flash memory devices, such as mirrorbit devices, exhibiting improved reliability at high manufacturing throughout and at a reduced cost. Semiconductor memory devices produced in accordance with the present invention enjoy industrial applicability in various commercial electronic devices, such as computers, mobile phones, cellular handsets, smartphones, set-top boxes, DVD players and recorders, automotive navigation, printers and peripherals, networking and telecom equipment, gaming systems, and digital cameras.

In the preceding detailed description, the present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method of fabricating a semiconductor device, the method comprising:
forming two gate electrode structures, spaced apart by a gap, on a semiconductor substrate;
forming dielectric sidewall spacers, having undercut regions, on side surfaces of the gate electrode structures;
depositing a conformal dielectric liner comprising: (a) silicon oxide at a thickness of about 50 Å to about 500 Å; or (b) a material other than silicon oxide into the gap and into the undercut regions; and
depositing a layer of dielectric material on the conformal dielectric liner and into the gap.

2. The method according to claim 1, wherein the step of depositing the conformal dielectric liner includes depositing (a) silicon oxide at a thickness of about 50 Å to about 500 Å; (b) silicon nitride; (c) silicon oxynitride; (d) silicon carbide; or (e) silicon oxycarbide.

3. The method according to claim 1, wherein the dielectric sidewall spacers comprise:
an oxide liner extending along a side surface of the gate electrode stack and along an upper surface of the substrate; and
a nitride layer on the oxide liner.

4. The method according to claim 2, comprising depositing the conformal silicon nitride layer at a thickness of 50 Å to about 500 Å.

5. The method according to claim 2, comprising depositing the layer of silicon oxide as the conformal dielectric liner.

6. The method according to claim 5, comprising depositing the conformal dielectric liner by atomic layer deposition or pulsed deposition.

7. The method according to claim 1, comprising depositing the layer of dielectric material into the gap by either:
depositing a layer of boron and phosphorous-doped silicate glass (BPSG) and annealing at a temperature of about 720° C. to about 840° C.; or
depositing a layer of phosphorous-doped high density plasma (H-HDP) oxide without annealing.

8. The method according to claim 7, wherein the gate electrode structures comprise an upper layer of nickel silicide, the method comprising depositing the layer of dielectric material by depositing the P-HDP oxide without annealing.

9. The method according to claim 8, comprising depositing the conformal dielectric liner and P-HDP oxide layer at a temperature less than 430° C.

10. The method according to claim 1, wherein each gate electrode structure comprises:
a gate dielectric stack comprising a first oxide layer, a nitride layer on the first oxide layer, and a second oxide layer on the nitride layer; and
a gate electrode on the gate dielectric stack.

11. The method according to claim 1, comprising depositing the conformal dielectric liner by atomic layer deposition or pulsed deposition.

12. A semiconductor device comprising:
two gate electrode structures, spaced apart by a gap, on a semiconductor substrate;
dielectric sidewall spacers, having undercut portions, on side surfaces of the gate electrode structures;
a conformal dielectric liner comprising: (a) silicon oxide at a thickness of about 50 Å to about 500 Å; or (b) a material other than silicon oxide into the gap and into the undercut regions; and
a layer of dielectric material on the conformal dielectric liner and in the gap.

13. The semiconductor device according to claim 12, wherein the conformal dielectric liner comprises (a) silicon oxide having a thickness of about 50 Å to about 500 Å; (b) silicon nitride; (c) silicon oxynitride; (d) silicon carbide; or (e) silicon oxycarbide.

14. The semiconductor device according to claim 12, wherein the dielectric sidewall spacers comprise:
an oxide liner extending along a side surface of the gate electrode stack and along an upper surface of the substrate; and
a nitride layer on the oxide liner.

15. The semiconductor device according to claim 13, wherein the conformal dielectric liner comprises silicon nitride at a thickness of about 50 Å to about 500 Å.

16. The semiconductor device according to claim 13, wherein the conformal dielectric liner comprises silicon oxide.

17. The semiconductor device according to claim 12, wherein the gate electrode structure comprises an upper layer of nickel silicide.

18. The semiconductor device according to claim 12, wherein each gate electrode structure comprises:
a gate dielectric stack comprising a first oxide layer, a nitride layer on the first oxide layer, and a second oxide layer on the nitride layer; and
a gate electrode on the gate dielectric stack.

19. The semiconductor device according to claim 16, wherein the silicon oxide includes nitrogen and carbon content.
